(19) United States
(12) Patent Application Publication
(10) Pub. No.: US 2015/0303345 A1
(43) Pub. Date: Oct. 22, 2015

(54) AMPLIFIED DETECTOR FORMED BY LOW TEMPERATURE DIRECT WAFER BONDING

(71) Applicant: UNIVERSITY COLLEGE CORK - NATIONAL UNIVERSITY OF IRELAND, CORK, Cork (IE)

(72) Inventors: Farzan Gity, Cork (IE); Brian Corbett, Cork (IE); Alan Morrison, Co. Cork (IE); John Hayes, Cork (IE)

(73) Assignee: University College Cork-National University of Ireland, Cork, Cork (IE)

(21) Appl. No.: 14/646,649

(22) PCT Filed: Nov. 25, 2013
(86) PCT No.: PCT/EP2013/074653

§ 371 Date: May 21, 2015

(30) Foreign Application Priority Data
Nov. 23, 2012 (GB) 1221079.5

(51) Int. Cl. H01L 31/109; H01L 27/146; H01L 31/0216

(52) U.S. Cl. CPC H01L 31/109; H01L 31/02161; H01L 27/1465

(57) ABSTRACT

In one embodiment the invention relates to a photodetector device sensitive for wavelengths comprising a doped Ge absorbing material bonded to a substrate material locally of opposite doping polarity and an interface layer formed between the Ge absorbing material and the substrate material to form a p-n junction. In one embodiment the bonded material comprises a p-doped Ge wafer and n-doped Si or So I wafer and obtained from a low-temperature heat treatment after bonding. The invention also discloses a process for making a photodetector.

### FIELD

The invention relates to a semiconductor device. In particular the invention relates to an amplified Ge/Si detector and process for making same.

### BACKGROUND

There is a need for Complementary Metal Oxide Semiconductor (CMOS) integrated (low cost and high function) high efficiency, low dark current optical detectors sensitive to wavelengths beyond that of silicon (1 micron). Applications in measuring and imaging await as do applications in communication receivers.

Ge is a suitable absorbing material and can be integrated with Si by epitaxial growth or wafer bonding. The quality of Ge layers deposited by epitaxial techniques is poor and uses high growth temperatures far beyond the thermal budget of CMOS. Deposition of Ge into selected regions with and without re-melting have been more successful but at the expense of high temperature steps and these detectors are only suitable for in-plane waveguide detection when used in a silicon on insulator (SOI) platform.

Conventional optical components are typically made of III-V compound materials such as gallium arsenide (GaAs) and indium phosphide (InP) due to their excellent light emission and absorption properties. Unfortunately, compound-semiconductor devices are generally complicated to process and costly to implement. More importantly, their fabrication processes are not compatible with CMOS. In search for a cost-effective solution, Ge materials can be used which are CMOS-compatible. Different approaches for integration have been investigated. Those using high-temperature heat treatments lead to inter-diffusion of Si and Ge. The lowered Ge concentration in the absorption region increases the active region band gap, resulting in reduced absorption coefficient particularly at longer wavelengths. Epitaxial growth suffers from the number of process steps which should be done in special systems (e.g. MBE or UHV-CVD) as well as additional ion implantation steps. Among other techniques wafer bonding has been proposed for realising waveguide photo-detectors. To date the conductivity across the interface has not been suitable for high quality photodetectors.

A number of patent applications around wafer boding for use in photovoltaics have been disclosed, for example U.S. Pat. No. 7,141,834, entitled ‘Method of using a germanium layer transfer to Si for photovoltaic’ (Filing date: Jun. 24, 2005); U.S. Pat. No. 7,755,109 “Ge/Si and other nonsilicon film heterostructures are formed by hydrogen-induced exfoliation of the Ge film”. U.S. 2011/0284926 A1 AVALANCHE PHOTODIODE STRUCTURE Filing date: May 18, 2011 discloses a GaAs PD grown on Ge substrate for dual band operation.

U.S. 2006/194418 entitled ‘Smooth Surface Liquid Phase Epitaxial Germanium’ discloses a method for smoothing a liquid phase epitaxy (LPE) germanium (Ge) film. U.S. 2012/0025212 discloses a photodiode with GeSn (germanium-tin) on top of a silicon layer requiring three active layers or materials a Germanium, Tin and Silicon are required resulting in poor performance devices that are technically difficult to make.

There are two major problems with direct wafer bonding which relate to the bond strength so that it can tolerate all the process steps and the nature of the interface between the two materials. The absorption coefficient of Ge is small at wavelengths close to its band-edge and so requiring thick layers to have complete absorption.

It is therefore an object of the invention to provide a detector device and method of making same to provide a device to overcome at least one of the above problems.

### SUMMARY

According to the invention there is provided, as set out in the appended claims, a photodetector device sensitive for wavelengths of greater than 1 micron comprising a low doped Ge absorbing material, for example a crystalline Ge wafer, bonded to a substrate material locally of opposite doping polarity and an interface layer formed between the Ge absorbing material and the substrate material to form a p-n junction.

In one embodiment the bonded material comprises a p-doped Ge wafer and n-doped Si wafer and obtained from a low-temperature heat treatment after bonding.

The invention demonstrates a high efficiency detection of photons with wavelength >1400 nm from a Ge-Si system where the light is incident normal to is the surface of the detector. The device of the invention allows a two dimensional array of detectors to be realized as could be used in a camera in one application of the invention.

In one embodiment the interface layer comprises a thickness of less than 10 nm.

In one embodiment the Ge and Si material on both sides of the junction are single crystalline in structure.

In one embodiment the photodetector comprises a photocurrent that is superlinearly sensitive to photogenerated carriers.

In one embodiment the photodetector is produced from a timed plasma surface activation before bonding.

In one embodiment an anti-reflection coating is provided and adapted to increase responsivity.

In one embodiment the p-n junction is adapted to facilitate transport of minority carriers across the junction.

In one embodiment the Ge material is bonded to the substrate material through a heat treatment using a temperature of less than 400 degrees celsius.

In one embodiment the substrate material comprises a Si wafer.

In one embodiment the substrate material comprises a Silicon on Insulator wafer.

In one embodiment the substrate material comprises a patterned Silicon wafer.

In one embodiment there is provided at least two photodetector devices on the is patterned wafer configured such that a first photodetector is configured to respond to the infrared through the Ge and a second photodetector to respond to the near-IR/visible with the Si. In this embodiment a two colour camera, one responding to the infra red through the Ge and one to the near-IR/visible with the Si can easily be made.

In one embodiment there is provided the step of doping a Ge absorbing material; bonding the Ge absorbing material to a substrate material locally of opposite doping polarity and an interface layer formed between the Ge absorbing material and the substrate material to form a p-n junction; and applying a low-temperature heat treatment after bonding.

In one embodiment there is provided the step of performing a timed oxygen surface activation before bonding.

In one embodiment there is provided the step of applying an anti-reflection coating to increase responsivity.

In one embodiment the Ge material is bonded to the substrate material through a heat treatment using a temperature of less than 400 degrees celsius.

In one embodiment there is provided the step of thinning the Ge material before processing.

In one embodiment the thinning step is performed using at least one of: CMP; etch or exfoliation process.

In a further embodiment there is provided a photodetector device comprising a lowly doped Ge wafer material of one doping type bonded to a highly doped Si wafer material of essentially the opposite doping type with a thin (<10 nm) interfacial barrier layer.

In one embodiment a p-doped Ge wafer and n-doped Si wafer are bonded where a delayed low-temperature heat treatment is applied after bonding.

In one embodiment the process comprises the step of performing a timed oxygen surface activation before bonding.

In one embodiment the process comprises the step of applying an anti-reflection coating to increase responsivity.

Lowly p-doped Ge and highly n-doped Si wafers are bonded and the majority of the Ge substrate is removed using Chemical Mechanical Polishing (CMP). The thickness of the remaining high quality Ge layer can be controlled in this step (from 1 μm to tens of μm) depending on the application. The bond strength and the nature of the interface can be improved by performing a timed oxygen surface activation prior to bonding.

Carrier transport across the interface is achieved by cleaning the wafers as well as a delayed low-temperature heat treatment after bonding. Remarkably high (amplified) photo-responsivity has been achieved at wavelengths as long as 1.62 microns.

The increase in current flow is due to an optically gated barrier according to one aspect of the invention.

The invention provides a low-cost, easy-to-fabricate and Si process-compatible Si/Ge integrated near infrared detectors. The invention can be applied to normal incidence illumination.

In one embodiment the invention can be used to make extended range photo-detectors and have them integrated with CMOS readout circuits. Dual band operation is envisaged with separate Ge and Si detectors.

### BRIEF DESCRIPTION OF THE DRAWINGS

The invention will be more clearly understood from the following description of an embodiment thereof, given by way of example only, with reference to the is accompanying drawings, in which:

FIG. 1 illustrates (a) Schematic illustration of the Ge/Si photodetectors made by wafer bonding technique followed by CMP. (b) High Resolution Transmission Electron Microscope (HR-TEM) image of the Ge/Si interface. The two zoomed-in images show a thin (−2 nm thick) interfacial layer (on the left) and a second interfacial region (on the right);

FIG. 2 illustrates (a) Dark current density versus reverse bias voltage (left axis) and C-V characteristic at 100 kHz (right axis) of the Ge/Si diode. The inset shows the I-V characteristics at two different temperatures.

Dashed lines are at 20° C. and solid lines are at −50° C. (b) 1/C² versus reverse bias voltage at 20° C. and −50° C. The value of the built-in potential (ψ_{bi}) is shown. The inset of part (b) shows the depletion width as a function of reverse bias voltage at 20° C. and −50° C. The shaded region illustrates the effect of charges captured by the interface traps at 20° C.;

FIG. 3 is a schematic representation of the Ge/Si band diagram at equilibrium at (a) −50° C., and (b) 20° C. ψ_{bi} and ψ_{Bp} are the built-in potential and the Fermi potential with respect to the midgap in the bulk of p-Ge, respectively. In part (a), the Ge surface at the interface is in the “weak inversion” mode while in part (b) it is in the “accumulation” mode. The dashed lines in (a) and (b) are the intrinsic Fermi level;

FIG. 4 (a) Responsivity of the Ge/Si photodiode versus input optical power at a wavelength of 1.55 μm and V=−2 V at two temperatures. (b) Responsivity as a function of wavelength at a constant optical power of 40 μW at different reverse bias voltages and temperatures; and

FIG. 5 illustrates a measured photocurrent as a function of bias and input power for a 20 micron diameter mesa photodetector.

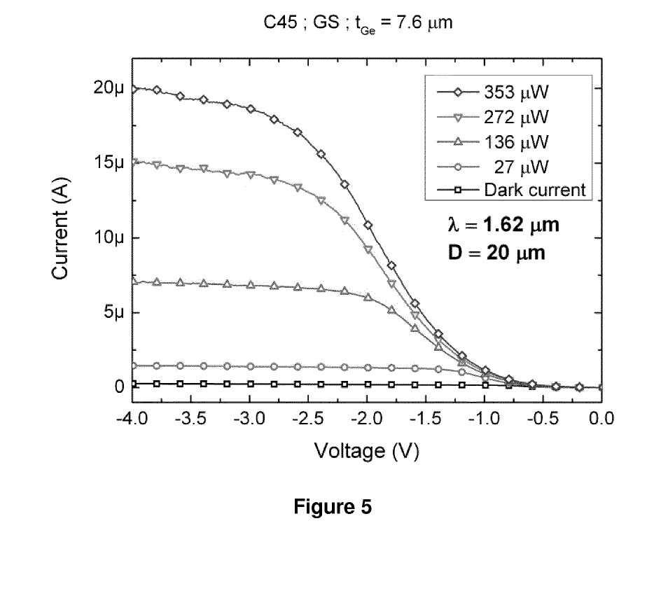

### DETAILED DESCRIPTION OF THE DRAWINGS

The invention provides a device with a conductive interface where the carrier conduction is strongly controlled by absorbed light by using low-temperature direct wafer bonding wherein the conductive interface layer formed between a Ge absorbing material and a substrate material provides a p-n junction. The inventive device is realised by a low temperature and wafer scale method and it produces detectors with an amplified response at long wavelengths. In one embodiment the invention can be extended to Ge on SOI as well as Ge on GaAs, etc.

The invention provides a Ge/Si photo-detector device with a responsivity of >3.5 A/W at a wavelength of 1.55 microns and a low dark current density of 48 mA/cm² at −2 V. The result is unique being compatible with surface normal illumination and capable of being integrated with CMOS electronics.

The process can be implemented on planarised Si and thus demonstrate a functioning 2D array of devices connected to on chip electronics.

### Embodiment

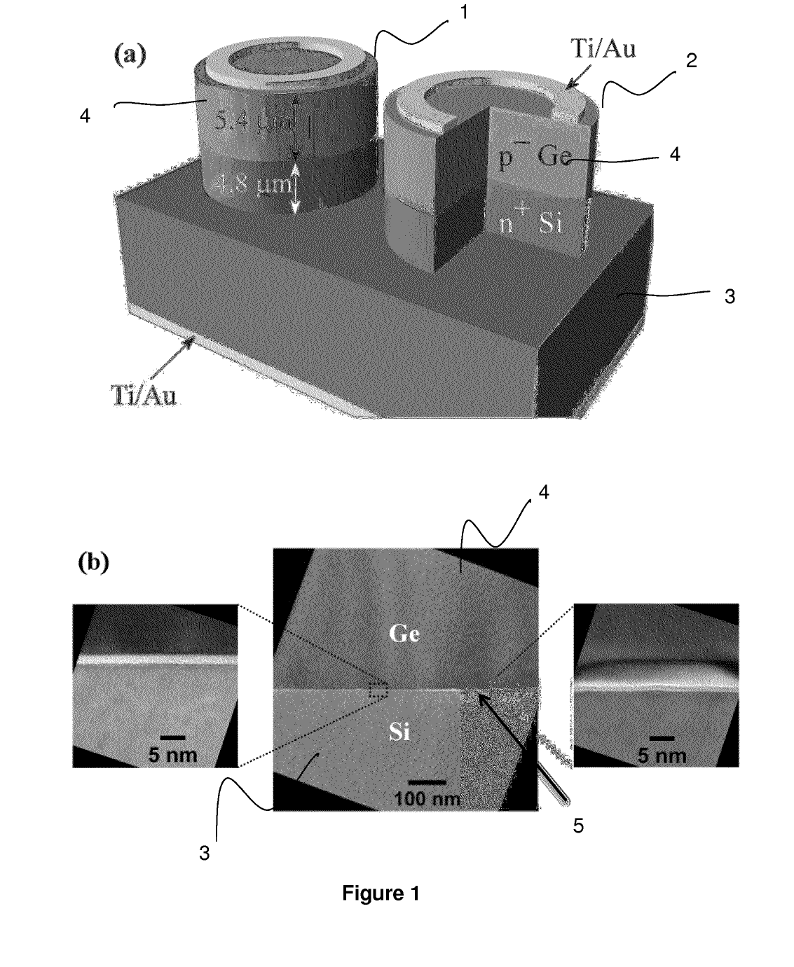

FIG. 1(a) illustrates a schematic of two Ge/Si photodetectors 1, 2 made by wafer bonding technique according to one embodiment of the invention.

A n+-Si wafer 3 (resistivity≈0.001 Ω.cm, thickness ≈535 μm) and a p⁻-Ge wafer 4 (resistivity ≈1 Ω.cm, doping level, Nₐ,≈3.5×10¹⁵ cm⁻³, thickness ≈510 μm) were chemically cleaned and then bonded at 10⁻⁵ mbar. The surface activation step can be performed by exposing the surface of the wafers to oxygen free radicals generated by a remote plasma ring at 100 W prior to bringing the wafers into direct contact. This step was followed by two 24-hour ex situ anneal steps at 200° C. and 300° C. in order to enhance the bond strength. Following the bonding, the Ge side of the bonded pair was thinned by mechanical grinding and polishing leaving a 5.4 μm thick Ge layer 4. The final thickness depends on the thinning process control capabilities and the bond is strength.

No delamination was observed after the grinding and polishing steps. In order to characterise the electrical and optical properties of the Ge/Si heterojunction mesa diodes were fabricated (FIG. 1(a)). Ohmic contacts were made to the p-Ge and n⁺-Si using Ti/Au (25/250 nm) deposited by e-beam evaporation. Circular mesa structures ranging in diameter from 100 μm to 500 μm were formed by SF₆/C₄F₈ inductively coupled plasma etching through the Ge/Si junction to a total depth of 10.2 μm.

An annealing step can be carried out for 30 min at 400° C. in H₂/N₂ (0.05/0.95) atmosphere. The entire fabrication process is done with the temperature 400° C. and is compatible with the backend processing of CMOS microelectronics.

### Results

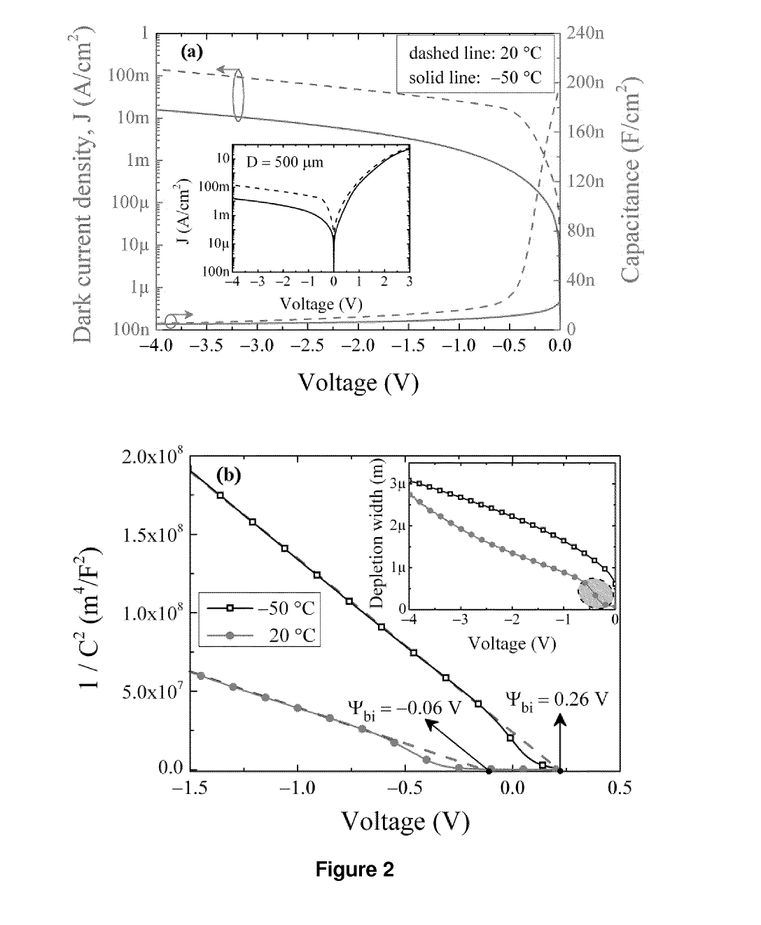

A high-resolution transmission electron micrograph (HR-TEM) of the Ge/Si heterojunction is shown in FIG. 1(b). The Ge and Si on both sides of the junction are single crystalline without any cracks or dislocations. An amorphous interfacial region or conductive interface layer 5 is observed to be approximately 2 nm thick. However, there are additional regions at the interface there on the Ge side, which are shown in the magnified images. FIG. 2(a) shows the dark current density (J) of a 500 μm-diameter device as a function of reverse bias (left axis) at two different temperatures. As can be seen, the reverse current is temperature dependent and the activation energy (Eₐ) obtained by performing current-voltage (I-V) measurements at different temperatures is 0.22 eV at −2 V. Eₐ decreases slightly at higher reverse bias voltages.

Capacitance-voltage (C-V) measurements were performed at 20° C. and −50° C. and at different frequencies (10 kHz to 1 MHz) in order to understand the variation in depletion width which will be occur mainly on the lightly doped Ge side of the junction.

is FIG. 2(a) shows how the capacitance depends on the reverse bias voltage at 20° C. and −50° C. (right axis). The C-V characteristics are independent of frequency at −50° C. while at 20° C. the capacitance at V>−1 V increases at lower frequency. This shows that interfacial traps are a factor and that these traps are being filled at room temperature. The inset of FIG. 2(a) illustrates the J-V characteristics of the device at two temperatures. This figure clearly shows the rectifying behaviour of the p-n heterojunction and that the thin interfacial layer does not block carrier transport. The dark current at −0.5 V, −1 V, and −2 V is 30 μA, 49 μA, and 94 μA, respectively which corresponds to dark current densities of 15 mA/cm², 25 mA/cm², and 48 mA/cm². These values compare very favourably with those reported to date for Ge/Si heterojunction photodetectors. The dark current density of devices with different diameters shows that the main component of the reverse current is due to the area of the device.

FIG. 2(b) shows how 1/C² depends on voltage at −50° C. and 20° C. at 100 kHz. As 1/C²=2(ψ_{bi}−V_{bias}−2 kT/q)/(qεNₐ), the extrapolation to 0 V defines the built-in potential (ψ_{bi}) of Ge at the interface. k, T, q, ε, and Nₐ are the Boltzmann constant, temperature, electronic charge, permittivity, and impurity concentration, respectively. The slope of the 1/C² versus voltage curve gives the carrier concentration in Ge which is 2×10¹⁵ cm⁻³ and −6.5×10¹⁴ cm⁻³ at 20° C. and −50° C., respectively. is positive at −50° C. which means that the Ge surface at the junction is depleted of holes, while the negative value of ψ_{bi} at 20° C. suggests that the Ge surface at the interface is in the accumulation regime.

This accumulation of holes at the Ge/Si interface is an indication of the presence of negative charges at the interface that attracts holes from Ge substrate toward the interface.

Considering the Ge surface potential (ψₛ) at the interface, the amount of charge at the interface (Qₛ) which is a function of ψₛ is Q_{s@20° C.}=+1.26×10⁻⁸ C/cm². This leads to the density of traps below E_{F} to be N_{s@20° C.}=Q_{s@20° C.} /q=7.88×10¹⁰ cm⁻². The depletion width (W_{D}) is also shown in the inset of FIG. 2(b) as a function of reverse bias voltage at the two temperatures. At −50° C. and 0 V, the is junction is already depleted and the W_{D} is ˜0.5 μm which then expands to 2.8 μm at −4 V. At 20° C., however, the expansion of the depletion region occurs after ˜−0.25 V (shaded area in the inset of FIG. 2(b)). This is due to the pile up of holes at the interface, which should be swept away by the electric field to reach the flat-band condition before depletion starts.

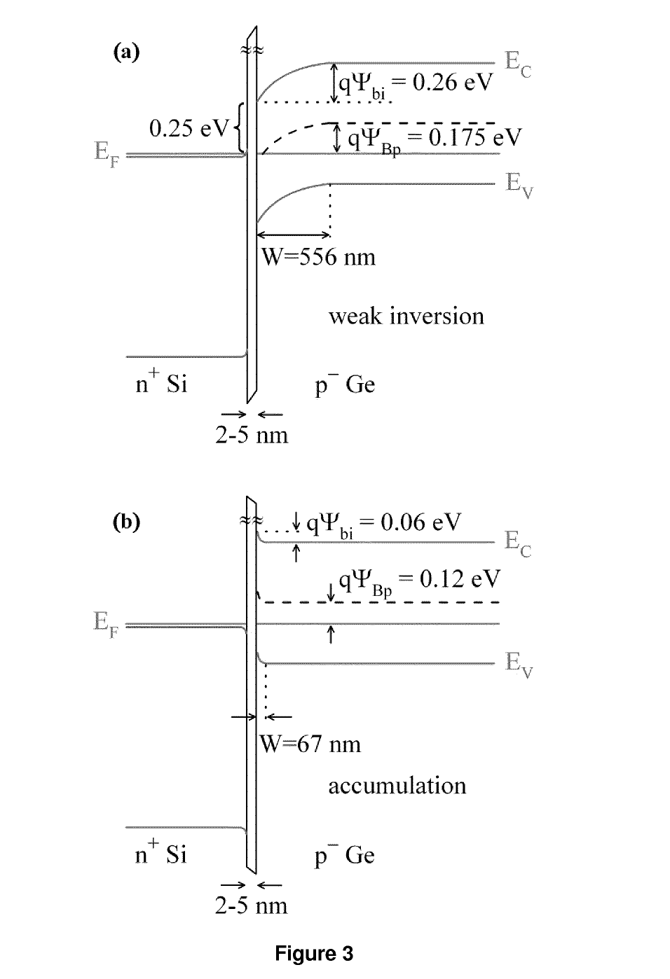

Based on the above, the band diagrams for the Ge/Si bonded interface at equilibrium at −50° C. and 20° C., are shown in FIGS. 3(a) and 3(b) respectively. At −50° C. the interface traps are thermally inactive and by increasing the reverse bias voltage both the surface potential and the depletion width increase and the current mechanism is suggested to be direct tunnelling from the Ge conduction band to the Si conduction band through the interfacial layer. At 20° C., however, the interface traps below E_{F} are active and cause upward band bending of Ge at the interface, thus lowering the potential barrier for carrier transport by thermionic field emission from the Ge to Si conduction band. Regarding the forward bias regime and as is shown in the inset of FIG. 2(a), there is a slow increase in the current both at −50° C. and 20° C. and is attributed to the large band offset between Si and Ge conduction band edges and to the presence of the interfacial layer.

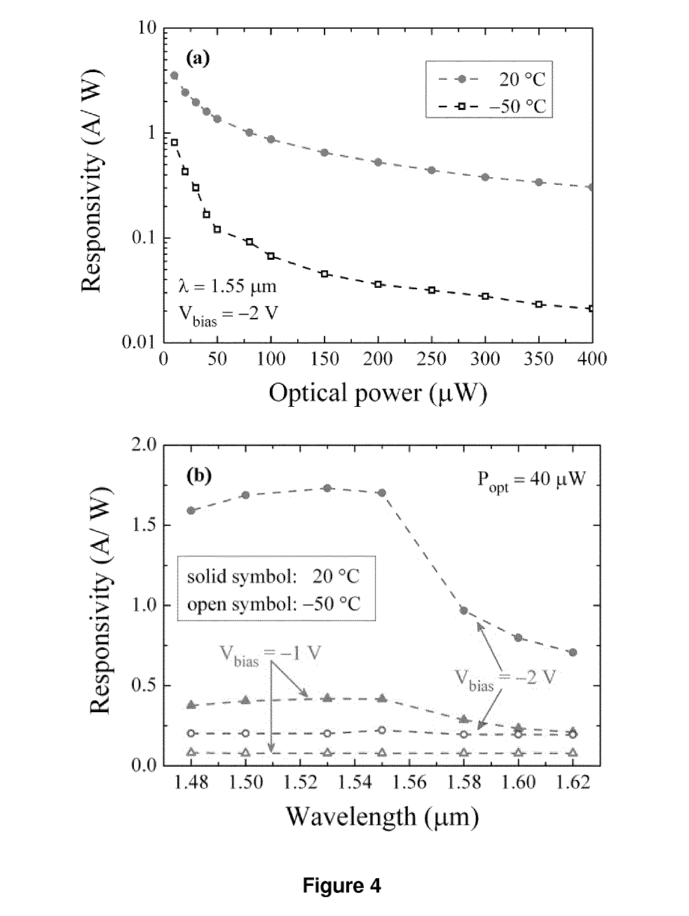

The photoresponse of the 500 μm-diameter mesa which has 320 μm-diameter open aperture at wavelength of 1.55 μm with a bias, V_{bias}, of −2 V, and at −50° C. and 20° C. is shown in FIG. 4(a). The light is delivered to the detector through a standard cleaved single mode fibre and illuminates a spot much less than the open aperture of the detector. A remarkably high responsivity is measured and is well in excess of one electron per photon even if all photons were absorbed, which is not the case. If the absorption coefficient of Ge at 1.55 μm is assumed to be 460 cm⁻¹ and thus only 13.5% of the incident light is absorbed in the 5.4 μm thick Ge layer. For an incident power of 10 μW the responsivity is 3.5 A/W at 1.55 μm and thus indicates current amplification by light induced barrier lowering. The interface traps are filled by the photo-excited electrons. These electrons cause band bending and therefore enhanced barrier lowering and increased thermionic field emission. To confirm this contribution, the built-in is potential of the detector is measured under illumination. A considerable increase from 0.06 V (in dark) to 0.51 V (under illumination at a wavelength of 1.62 μm, 10 μW) suggests that the photo-excited electrons are captured by the empty interface traps above E_{F}. As a result, the pile up of holes at the Ge/Si interface increases which leads to higher built-in potential.

The responsivity as a function of wavelength at different temperatures and at two bias voltages is shown in FIG. 4(b). The significant rise of the responsivity at −2 V at 20° C. compared to −1 V is likely to be due to the increase of the electric field at the Ge interface (Ge band bending) which in turn enhances the carrier transport by thermionic field emission.

For the first time the invention provides amplified responsivity for vertically illuminated Ge/Si photodiodes. The responsivity can be increased further with the use of an anti-reflection coating.

The amplification can be controlled through controlling the ratio between the total mesa diameter and the active area as defined by an aperture in the contact metal. The interface can be further engineered through the provision of very thin doped layers at the interface introduced into the wafers prior to bonding.

It will be appreciated that the invention demonstrates Ge photodetectors integrated with Si fabricated by CMOS-compatible low temperature wafer bonding. The mesa devices have a low dark current density of 25 mA/cm² at −1 V and 48 mA/cm² at −2 V respectively. Above unity responsivity has been measured at low incident powers due to the light induced potential barrier lowering. Band diagrams of the Ge/Si interface are proposed based on temperature dependent electrical measurements. Owing to the high responsivity, low dark current density and compatibility with CMOS processing, these devices can be integrated with Si-based read-out circuits for applications such as high-performance near infrared imaging.

It will be appreciated that in the context of the present invention the terms ‘photodetector’ and ‘photodiode’ can be used interchangeably and effectively have the same meaning that is apparent to someone skilled in the art.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A photodetector device comprising a doped Ge absorbing material bonded to a substrate material locally of opposite doping polarity and an interface layer formed between the Ge absorbing material and the substrate material to form a p-n junction.

2. The photodetector according to claim 1 wherein the bonded material comprises a p-doped Ge wafer and n-doped Si or SOI wafer and obtained from a low-temperature heat treatment after bonding.

3. A photodetector according to claim 1 wherein the interface layer comprises a thickness of less than 10 nm.

4. A photodetector according to claim 1 wherein a photocurrent is superlinearly sensitive to photogenerated carriers.

5. A photodetector according to claim 1 wherein the device is sensitive for wavelengths of greater than 1 micron.

6. A photodetector according to claim 1 produced from a timed plasma surface activation before bonding.

7. A photodetector according to claim 1 comprising an anti-reflection coating adapted to increase responsivity.

8. A photodetector according to claim 1 wherein the p-n junction is adapted to facilitate transport of minority carriers across the junction.

9. A photodetector according to claim 1 wherein the Ge material is bonded to the substrate material through a heat treatment using a temperature of less than or equal to 400 degrees celsius.

10. A photodetector according to claim 1 wherein the substrate material comprises a Si wafer.

11. A photodetector according to claim 1 wherein the substrate material comprises a Silicon on Insulator (SOI) wafer.

12. A photodetector according to claim 1 wherein the substrate material comprises a patterned Silicon wafer.

13. A photodetector according to claim 1 comprising at least two photodetector devices on the patterned wafer configured such that a first photodetector is configured to respond to the infrared through the Ge and a second photodetector to respond to the near-IR/visible with the Si.

14. A detector comprising amplified responsivity for vertically illuminated Ge/Si photodetectors produced according to claim 1.

15. An array of devices wherein at least one device comprises the phototdetector of claim 1.

16. A process for making a detector device comprising the step of doping a Ge absorbing material; bonding the Ge absorbing material to a substrate material locally of opposite doping polarity and an interface layer formed between the Ge absorbing material and the substrate material to form a p-n junction; and applying a low-temperature heat treatment after bonding.

17. The process of claim 16 comprising the step of performing a timed oxygen surface activation before bonding.

18. The process of claim 16 comprising the step of applying an anti-reflection coating to increase responsivity.

19. The process of claim 16 wherein the Ge material is bonded to the substrate material through a heat treatment using a temperature of less than 400 degrees celsius.

20. The process of any of claims 16 to 19 comprising the step of thinning the Ge material before processing.

21. (canceled)
